(19) United States
(12) Patent Application Publication
(10) Pub. No.: US 2007/0140946 A1
(43) Pub. Date: Jun. 21, 2007

(54) Dispersed growth of nanotubes on a substrate

(75) Inventors: Jean-Christophe P. Gabriel, Pinole, CA (US); Keith Bradley, Oakland, CA (US); Philip G. Collins, Irvine, CA (US)

Correspondence Address: O'MELVENY & MYERS LLP, 610 NEWPORT CENTER DRIVE, 17TH FLOOR, NEWPORT BEACH, CA, 92660, US

(73) Assignee: Nanomix, Inc.

(21) Appl. No.: 11/703,293

(22) Filed: Feb. 7, 2007

Related U.S. Application Data
(62) Division of application No. 10/177,929, filed on Jun. 21, 2002.

(51) Int. Cl. D01F 9/12

(52) U.S. Cl. 423/447.1

(57) ABSTRACT

Methods of forming a dispersion of nanostructures, a distribution of carbon nanotubes, and an array of nanostructure devices are described. The methods involve providing a substrate, applying growth promoter to at least a portion of the substrate, exposing the substrate and the growth promoter to a plasma, and forming a dispersion of nanostructures from the growth promoter after the plasma exposure. Exposing the substrate and the growth promoter to a plasma disperses at least a portion of the growth promoter as distinct, isolated growth promoter areas over the substrate. Preferably, the growth promoter areas are nanoparticles between about 1 nm and 50 nm in size and they are dispersed approximately uniformly over the substrate. An array of nanostructure devices is also described. The array of devices includes a substrate, a dispersion of nanostructures disposed discontinuously on the substrate and an array of electrodes in contact with the dispersion of nanostructures. The nanostructures may be nanotubes or nanowires. Preferably, the dispersion of nanostructures is approximately planar and substantially in contact with the substrate. Regions containing nanostructures can provide electrical communication between two or more electrodes.

### CROSS-REFERENCE TO RELATED APPLICATIONS

This application is a divisional application of U.S. patent application Ser. No. 10/177,929, filed Jun. 21, 2002, which is hereby incorporated by reference in its entirety as if fully set forth.

### BACKGROUND OF THE INVENTION

1. Field of the Invention

This invention relates generally to formation of nanostructure dispersions, and, more specifically, to methods for forming nanotube dispersions on substrates and for forming nanostructure devices.

2. Description of the Related Art

There has been much interest in using nanostructures as active components in electronic devices. The basic idea is to connect electrodes to nanostructures, thus forming an electric circuit. The nanostructures can be biased with a gate electrode to form devices such as transistors.

One approach has been to make the nanotubes first and then place them onto a prepared substrate. Conventionally, the nanotubes are formed either by arc-discharge or laser ablation techniques, which yield tangled bundles of nanotubes rather than single, isolated structures. A method for making carbon fibers using a carbon-vaporization method has been described by Bethune et al. in U.S. Pat. No. 5,424,054, and methods for making single-wall carbon nanotubes and ropes of carbon nanotubes using laser ablation have been described by Smalley, et al. in U.S. Pat. No. 6,183,714.

In order to use these nanotubes as device components, a liquid such as dichloromethane is added to the nanotubes to form a dilute solution in which the nanotube bundles are separated into single nanotubes. A substrate is prepared with metal electrodes on the surface. Drops of the nanotube solution are deposited onto the prepared substrate. But, it is difficult to achieve the nanotube density necessary to make contact to the electrodes reliably, even after many drops have been deposited. This is not a process that will be useful for large-scale manufacture of nanotube devices.

Another approach has been to grow the nanotubes directly on the substrate. A catalyst or growth promoter is disposed on the surface of the substrate and provides nucleation sites for growth of nanotubes by chemical vapor deposition. A method for growing carbon fibrils from catalyst particles deposited on thin films or plates has been described by Tennent et al. in U.S. Pat. No. 5,578,543. Colloidal techniques were used for precipitating uniform, very small catalyst particles that were deposited onto the substrates.

A letter to Nature entitled, “Controlled production of aligned-nanotube bundles,” by Terrones et al. and published Jul. 3, 1997, described a method of generating nanotubes from a patterned catalyst. A very thin layer of cobalt was deposited onto silica. Laser ablation was used to produce a uniform distribution of catalyst particles along the edges of lines eroded by the laser.

In another letter to Nature entitled, “Very long carbon nanotubes,” by Pan et al. and published Aug. 13, 1998, described a method of forming small regions of catalyst and subsequently growing carbon nanotubes from them. A sol-gel catalyst film was formed on a substrate. The film was dried and calcined, thus forming catalyst particles on the substrate.

A method for producing carbon nanotube structures from catalyst islands has been described by Dai et al. in U.S. Pat. No. 6,346,189. Catalyst islands about 1-5 μm in size were formed using a multi-step, e-beam lithographic process. Carbon nanotubes were grown from the islands using a chemical vapor deposition process. Individual nanotubes were incorporated into devices by locating islands and making electrical and mechanical connections to the nanotubes that had grown from the islands. This “localized” approach to nanotube device fabrication required that nanotube positions were known. Electrical contacts were made to the nanotubes at these known positions.

Dai et al. taught a method of synthesizing a film of nanotubes on a substrate in PCT Publication Number WO01/44796 A1. A catalyst layer was spin-coated onto a substrate, and a film of interconnected single-walled carbon nanotubes was formed using chemical vapor deposition. Metal electrodes were evaporated onto the nanotube film, thus forming a nanotube film device. The metal electrodes made contact with the nanotubes film and with the layer of catalyst, but not with the substrate. In this method the substrate acts merely as a holder for the nanotube devices as the catalyst film forms an insulating layer between the electrodes and nanotube film on one side and the substrate on the other. Also, the surface of the catalyst is very rough, which would cause poor contact deposition and adhesion, not compatible with semiconductor processing, and would therefore not be manufacturable.

In developing manufacturing processes for nanotube devices, it will be important to find the most efficient and fastest methods possible. Current methods for producing nanotubes and devices, such as those described above, are not compatible with low-cost, mass-production manufacturing, nor are they likely to yield devices that have good, long-term reliability. Therefore, there exists a need to develop alternative methods for forming nanostructures and devices to take advantage of this new technology. It would be of further benefit to use processes that are already well-known in the semiconductor industry.

A “statistical,” rather than a “localized” approach to nanostructure device fabrication can be used if a high density, good quality, random dispersion of individual nanostructures can be formed on a semiconductor substrate. In the “statistical” approach, electrical contacts can be placed anywhere on the dispersion of nanostructures to form devices. It is not necessary to make a specific correspondence between electrode position and nanostructure position, as the high density dispersion of nanostructures ensures that any two or more electrodes placed thereon will be able to form a complete electrical circuit with nanostructures as the conducting connector. It will be a further advantage to integrate nanotube devices into a semiconductor platform so that the nanotube devices can be connected to semiconductor devices within the substrate.

### SUMMARY OF THE INVENTION

In accordance with one aspect of the present invention a method of forming a dispersion of nanostructures is provided. The method involves providing a substrate, applying growth promoter to at least a portion of the substrate, exposing the substrate and the growth promoter to a plasma, and forming a dispersion of nanostructures from the growth promoter after the plasma exposure. The substrate can be made of materials such as silicon, silicon oxides, silicon nitride, alumina, or quartz. The growth promoter can contain elements such as gold, silver, copper, iron, molybdenum, chromium, cobalt, nickel, zinc, aluminum, or oxides thereof. Exposing the substrate and the growth promoter to a plasma disperses at least a portion of the growth promoter as distinct, isolated growth promoter areas over the substrate. Preferably, the growth promoter areas are nanoparticles between about 1 nm and 50 nm in size, and they are dispersed approximately uniformly over the substrate. Preferably, the nanostructures are formed using a chemical vapor deposition process. Preferably, the nanostructures are nanotubes, such as single-wall carbon nanotubes, or nanowires. Preferably, the dispersion of nanostructures is approximately planar and substantially in contact with the substrate surface. A plurality of electrodes in electrical contact with the dispersion of nanostructures can also be formed.

In accordance with another aspect of the invention, a method for forming a distribution of carbon nanotubes is provided.

In an illustrated embodiment, a method of forming an array of nanostructure devices is provided. The method involves providing a substrate, applying growth promoter to at least a portion of the substrate, exposing the substrate and the growth promoter to a plasma, forming a dispersion of nanostructures from the growth promoter after the plasma exposure, and forming an array of electrodes in contact with the dispersion of nanostructures. The method can further include removing portions of the dispersion of nanostructures either before or after forming the array of electrodes. The nanostructures can be removed with resist-lithography-etch processes.

In another embodiment, an array of nanostructure devices is provided. The array of devices includes a substrate, a dispersion of nanostructures disposed discontinuously on the substrate and an array of electrodes in contact with the dispersion of nanostructures. The substrate can be made of materials such as silicon, silicon oxides, silicon nitride, alumina, or quartz. Preferably, the nanostructures are nanotubes or nanowires. Preferably, the dispersion of nanostructures is approximately planar and substantially in contact with the substrate. The dispersion of nanostructures can contain carbon, silicon, germanium, arsenic, gallium, aluminum, boron, phosphorous, indium, tin, molybdenum, tungsten, vanadium, sulfur, selenium, and/or tellurium. The dispersion of nanostructures can include regions of nanostructures interspersed with areas containing no nanostructures. Regions containing nanostructures can provide electrical communication between two or more electrodes.

Further features and advantages of the present invention will become apparent to those of ordinary skill in the art in view of the detailed description of preferred embodiments below, when considered together with the attached drawings and claims.

### BRIEF DESCRIPTION OF THE DRAWINGS

The figures are for illustrative purposes only and are not drawn to scale.

FIG. 1 is a flow chart describing the steps for forming a dispersion of nanostructures according to an embodiment of the invention.

FIGS. 2A, 2B, 2C are perspective views illustrating the steps for forming a dispersion of nanostructures according to an embodiment of the invention.

FIGS. 3A, 3B are scanning electron microscope images of dispersions of carbon nanotubes formed according to an embodiment of the invention.

FIG. 4 is a flow chart describing the steps for forming an array of nanostructure devices according to an embodiment of the invention.

FIG. 5A, 5B, 5C, 5D, 5C′, 5D′ are top views illustrating the steps for forming an array of nanostructure devices according to two different processing arrangements.

FIG. 6A is a top view of a nanostructure dispersion disposed on a substrate according to an embodiment of the invention.

FIG. 6B is a cross-section view of a representative individual nanostructure from the nanostructure dispersion of FIG. 6A.

FIG. 7 is a top view of an array of nanostructure devices according to an embodiment of the invention.

### DETAILED DESCRIPTION OF THE PREFERRED EMBODIMENT

In order to make full use of nanostructures in device technology, it will be necessary to find ways to manufacture the devices that are efficient and cost-effective. Much of the work that has gone into developing nanostructure devices has been at the laboratory level using methods that are not appropriate for large-scale manufacturing. If a high density, good quality, random dispersion of individual nanostructures can be formed on a semiconductor substrate, then a “statistical,” rather than a “localized” approach to nanostructure device fabrication can be used. In the “statistical” approach, electrical contacts can be placed anywhere on the dispersion of individual nanostructures to form devices. It is not necessary to make a specific correspondence between electrode position and nanostructure position as in the “localized” approach, because the high density dispersion of nanostructures ensures that any two or more electrodes placed thereon can form a complete electrical circuit with functioning nanostructures providing the connection. Furthermore, true integration of nanotube devices into a semiconductor platform will allow nanotube devices to connect to semiconductor devices within the substrate.

The aforementioned needs are satisfied by the methods of the present invention which describe ways to disperse growth promoter nanoparticles over a substrate surface, thereby providing sites from which nanostructures can be formed in a high density dispersion.

The skilled artisan can readily appreciate that the materials and methods disclosed herein will have application in a number of contexts where large numbers of dispersed, individual nanostructures are desired, particularly where large-scale manufacturing is important.

The foregoing aspects and others will be readily appreciated by the skilled artisan from the following description of illustrative embodiments when read in conjunction with the accompanying drawings. Reference will now be made to the drawings wherein like numerals refer to like parts throughout.

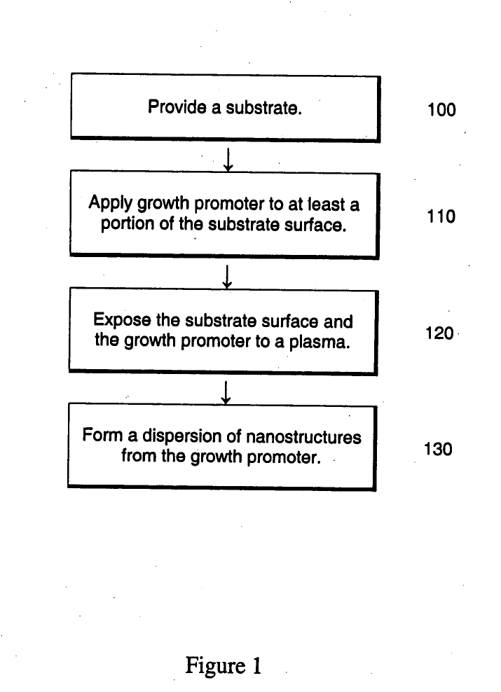

FIG. 1 is a flow chart that describes the basic steps for forming a dispersion of nanostructures according to an embodiment of the invention. For the purposes of this disclosure, a dispersion of nanostructures will be referred to also as a network or a distribution of nanostructures. These terms are used to mean a large number of individual nanostructures that are randomly spread out in two-dimensions. Some nanostructures may be in contact with one another, and some nanostructures may be isolated from the rest. Preferably the dispersion of nanostructures is approximately planar and is substantially in contact with an underlying substrate. Preferably, the nanostructures are single-wall nanotubes or nanowires. In step 100, a substrate is provided. The substrate can have a surface layer that is different from the underlying material. The substrate surface can consist of silicon, silicon oxide, silicon nitride, alumina, quartz, or any material consistent with the art of semiconductor manufacturing. In step 110, growth promoter is applied to at least a portion of the substrate surface. One or more growth promoter regions can be formed in a number of ways. Examples include depositing one or more drops of growth promoter in solution onto the substrate surface, such as with a chemical jet, and applying a film of growth promoter onto part or all of the substrate. Preferably, the growth promoter is a solution of catalyst particles mixed with a diluent containing intercalating particles made from materials such as polymers, ceramics, minerals or clay. Preferably, the catalyst particles contain gold, silver, copper, iron, molybdenum, chromium, cobalt, nickel, zinc, aluminum, oxides thereof, or any other material known to promote the growth of nanostructures. Examples include Fe(NO₃)₃, Fe(SO₄), and other iron salts, CoCl₂, and oxides of Fe, Mo, and Zn. In step 120, the growth promoter and the substrate are exposed to a plasma. The plasma can be an rf or a dc plasma. The plasma can contain gases such as oxygen, chlorine, fluorine, xenon hexafluoride, or any other gas known in the art of plasma etching. The plasma treatment in step 120 causes the growth promoter to be scattered in nanoparticle fragments across the substrate surface. In step 130, a dispersion of nanostructures is formed from the growth promoter on the substrate surface. Preferably the nanostructures are formed using a chemical vapor deposition process.

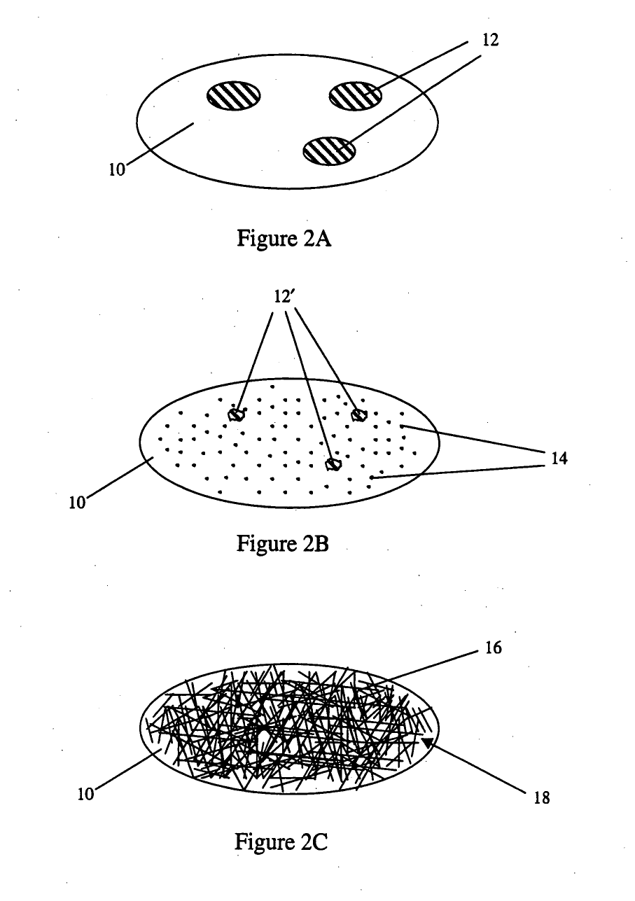

FIGS. 2A, 2B, and 2C are perspective views of a substrate at successive steps of the process for forming a dispersion of nanostructures according to an embodiment of the invention. FIG. 2A shows a substrate 10 with drops of growth promoter 12. Preferably, the substrate 10 is a silicon wafer, but it can be any material consistent with the art of semiconductor manufacturing. The substrate 10 can consist of one single material, or it can consist of any number of different material layers. Examples of surface layer materials include silicon, silicon oxide, silicon nitride, alumina, and quartz. The growth promoter 12 can be applied in any number of ways, for example, by depositing drops or by spin-coating a film. Preferably, the growth promoter 12 is a solution of catalyst particles mixed with a diluent containing intercalating particles. Examples of catalyst particles include Fe(NO₃)₃, Fe(SO₄), and other iron salts, CoCl₂, and oxides of Fe, Mo, and Zn.

FIG. 2B shows distinct, isolated nanoparticles 14 of growth promoter dispersed over the surface of the substrate 10 after the substrate and growth promoter 12 have been exposed to a plasma, as was described above for FIG. 1. The nanoparticles 14 vary in size between about 1 nm and 50 nm and are distributed in a random arrangement on the surface of the substrate 10. Preferably, the nanoparticles 14 are dispersed approximately uniformly over the substrate 10 surface. Alternatively, there may be regions of the substrate 10 where there are very many nanoparticles 14, and there may be regions where there are few or no nanoparticles 14. For some plasma treatment conditions, there can be small regions of growth promoter residues 12′ left from the original growth promoter regions 12 (as were shown in FIG. 2A) in addition to the nanoparticles 14. The skilled artisan will understand that varying the plasma conditions will cause variations in the distributions of growth promoter nanoparticles 14 on the substrate 10 surface. Examples of plasma treatment conditions include an rf oxygen plasma operated at 5 watts for 12 seconds and an rf oxygen plasma operated at 160 watts for 30 seconds. In general, higher energies and longer times result in greater dispersion of the growth promoter. Low energies and short times can result in of growth promoter residues 12′ and a distribution of growth promoter nanoparticles 14 that is more dense near the residues 12′ and has a density that decreases with distance from the residues 12′.

FIG. 2C shows a large number of randomly arranged and evenly distributed nanostructures 16 as formed from the growth promoter nanoparticles (not shown), which make up a nanostructure dispersion 18. Preferably, the nanostructure dispersion 18 is formed using a chemical vapor deposition process. Nanotubes, for example, single-wall carbon nanotubes, are desirable for many device applications. Examples of appropriate precursor gases for formation of carbon nanostructures in the chemical vapor deposition process include methane, acetylene, carbohydrate vapor, toluene, and benzene. Other nanostructures can be formed using other precursor gases. Precursor gases containing silicon, germanium, arsenic, gallium, aluminum, phosphorous, boron, indium, and tin are known to form nanostructures such as nanowires. For ease of illustration, no growth promoter nanoparticles or growth promoter residues are shown in FIG. 2C, but they can be present after formation of the nanostructures 16. Usually, a growth promoter nanoparticle 14 is attached at one end of each nanostructure 16.

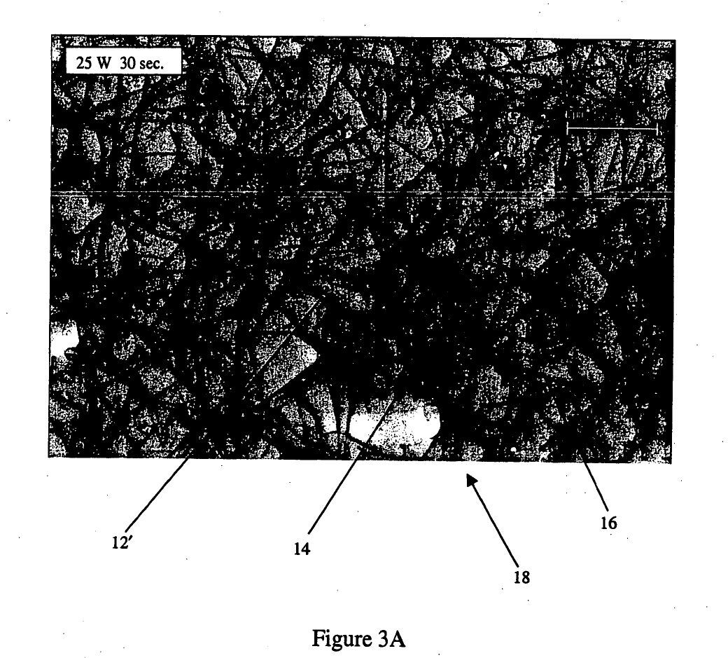

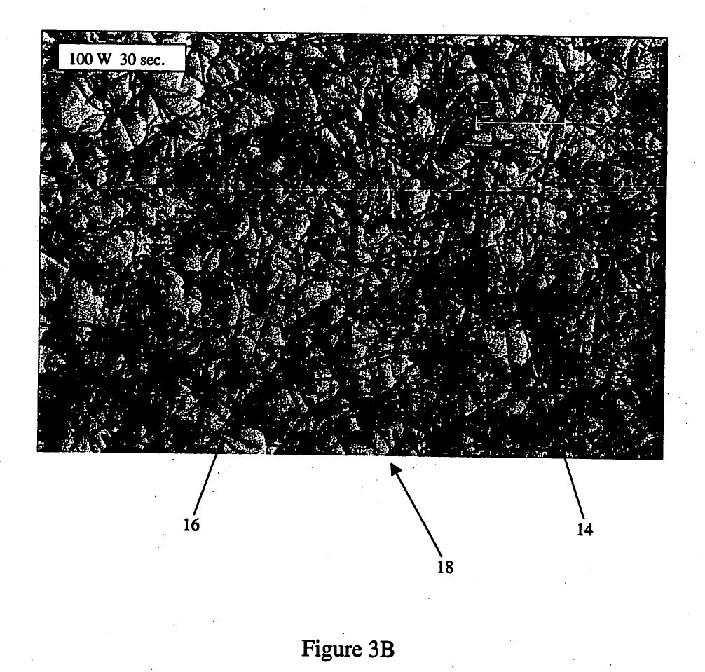

FIGS. 3A and 3B are scanning electron microscope images of dispersions 18 of carbon nanotubes formed from growth promoter nanoparticles that were formed with different plasma conditions. Growth promoter droplets containing a mixture of iron nanoparticles, alumina chemical precursors, and surfactant were deposited onto silicon wafers. The sample in FIG. 3A underwent an rf oxygen plasma treatment at 25 watts for 30 seconds. The sample in FIG. 3B underwent an rf oxygen plasma treatment at 100 watts for 30 seconds. Subsequently, carbon nanotubes 16 were formed on each sample using chemical vapor deposition with methane. The nanotubes 16 in both FIGS. 3A and 3B are distributed over the substrate uniformly. The density of the nanotubes 16 that make up the dispersion of nanotubes in FIG. 3A is lower than in FIG. 3B. The difference in nanotube density indicates that there was a lower density of growth promoter particles before nanotube formation for the substrate in FIG. 3A than for the substrate in FIG. 3B. The lower power plasma used in FIG. 3A caused the growth promoter particles to be less dispersed, i.e., fewer in number and less densely spread out. In FIG. 3A, growth promoter residue 12′ can also be seen. An example of a growth promoter nanoparticle 14 is also indicated in both FIG. 3A and FIG. 3B.

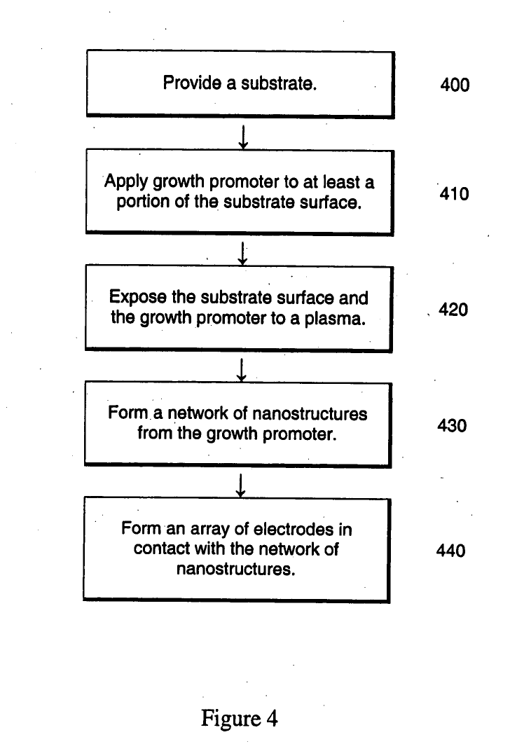

FIG. 4 is a flow chart that describes the basic steps for forming an array of nanostructure devices according to another embodiment of the invention. The first four steps 400-430 are as described for forming a dispersion of nanostructures in FIG. 1. In step 400, a substrate is provided. The substrate can be a silicon wafer or any substrate consistent with the art of semiconductor manufacturing. In step 410, growth promoter is applied to at least a portion of the substrate surface. The growth promoter can be applied in any of a number of ways. One or more drops of growth promoter in solution can be deposited. Alternatively, a film of growth promoter can be applied onto part or all of the substrate. Preferably, the growth promoter is a solution of catalyst particles mixed with a diluent containing intercalating particles made from materials such as polymers, ceramics, minerals or clay. Preferably, the catalyst particles contain gold, silver, copper, iron, molybdenum, chromium, cobalt, nickel, zinc, aluminum, oxides thereof, or any other material known to promote the growth of nanostructures. Examples include Fe(NO₃)₃, Fe(SO₄), and other iron salts, CoCl₂, and oxides of Fe, Mo, and Zn. In step 420, the growth promoter and the substrate are exposed to a plasma. The plasma can be an rf or a dc plasma. The plasma can contain gases such as oxygen, chlorine, fluorine, xenon hexafluoride or any other gas used in the art of plasma etching. The plasma treatment in step 420 causes the growth promoter to be scattered in nanoparticle fragments across the substrate surface. Preferably, the growth promoter nanoparticles are distributed homogeneously over the substrate surface. Although for plasma treatments having low power and short time, there can be growth promoter residues from the original growth promoter regions remaining, and the nanoparticles can have a higher density near the original growth promoter regions, which decreases with distance from the original growth promoter regions. In step 430, a network of nanostructures is formed from the growth promoter on the substrate surface. Preferably the nanostructures are formed using a chemical vapor deposition process. In step 440, an array of electrodes is formed in contact with the network of nanostructure. At least one region in the network of nanostructures provides electrical communication between at least two electrodes. In other arrangements, there can be more than two electrodes that are in electrical communication with one another through a region or regions of the network of nanostructures.

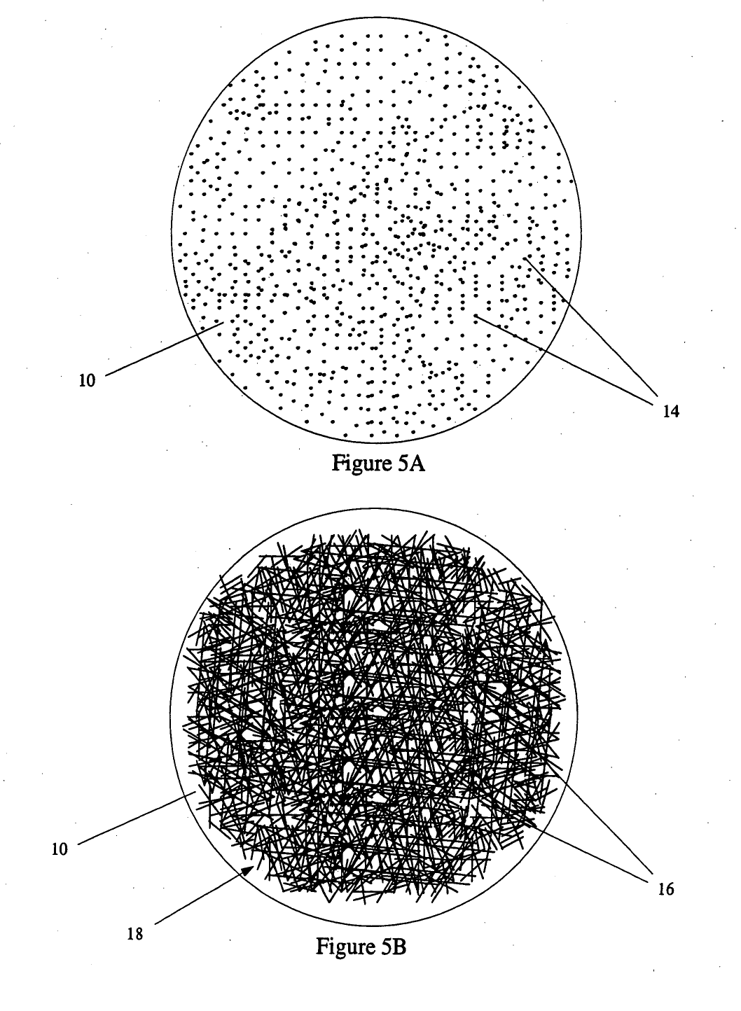

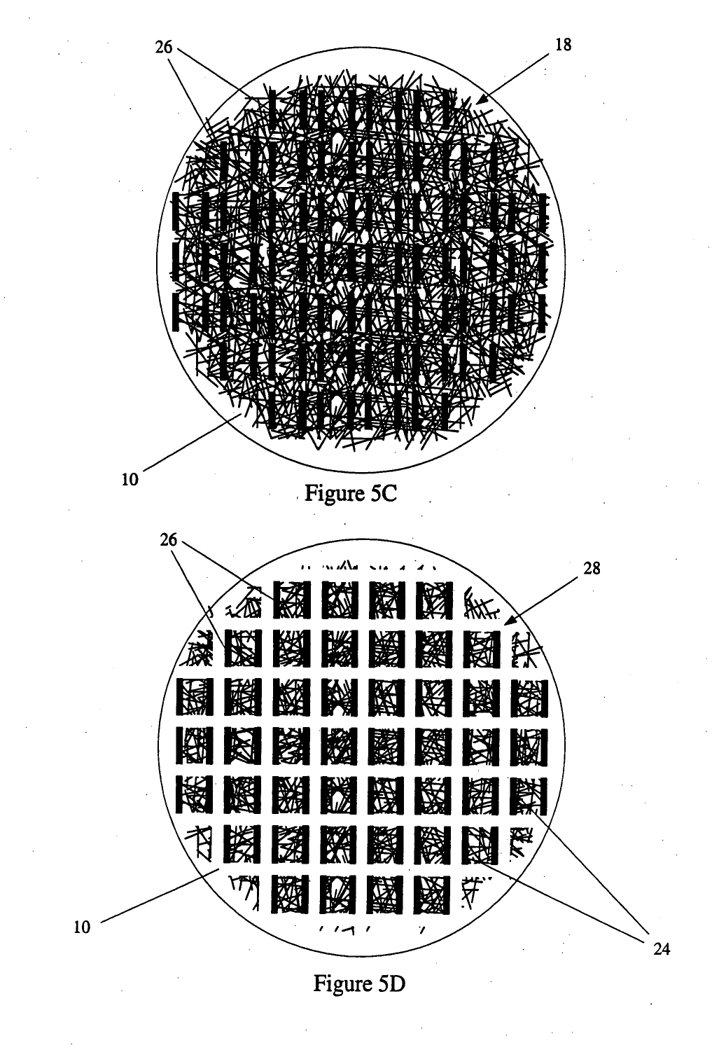

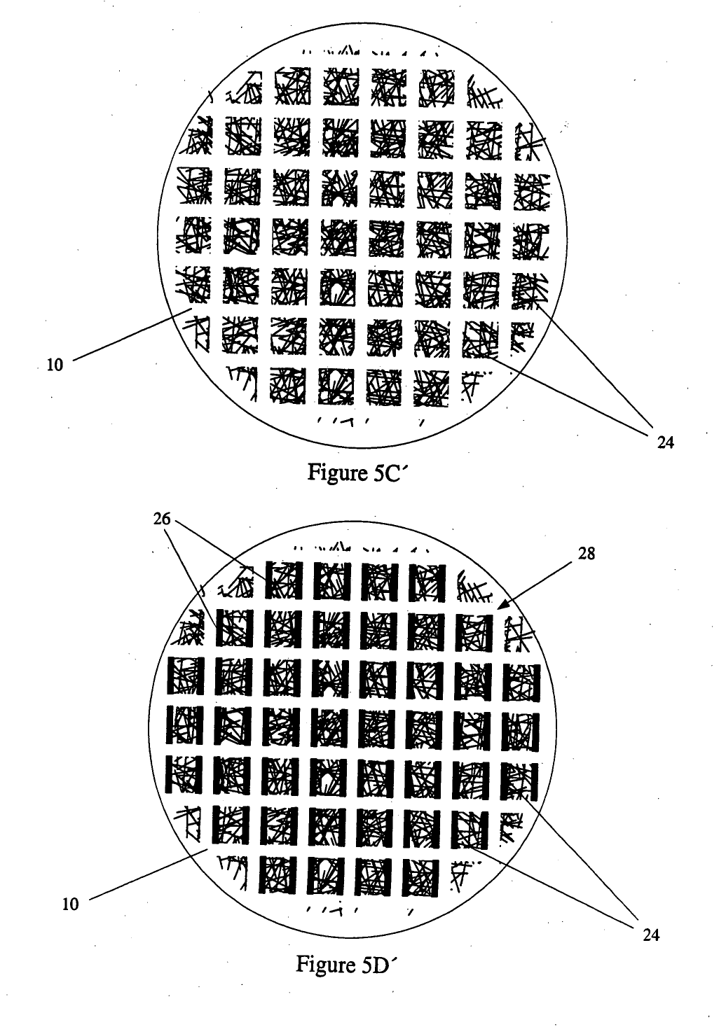

The result of the steps discussed in FIG. 4 is an array of nanostructure devices made up of regions of nanostructure network wherein each region is in contact with at least two electrodes. The nanostructure devices can each function independently when they are electrically isolated from one another, i.e., there is no electrical communication between devices through the nanostructure network. One method is to intersperse nanostructure regions that are the active parts of the nanostructure devices with regions that contain no nanostructures. This will be discussed below with reference to FIG. 5.

FIGS. 5A, 5B, 5C, 5D are top views of a substrate at successive steps of a process for forming an array of nanostructure devices according to one arrangement. FIGS. 5A, 5B, 5C′, 5D′ are top views of a substrate 10 at successive steps of a process for forming an array of nanostructure devices according to an alternative arrangement. FIG. 5A shows nanoparticles 14 of growth promoter dispersed over a substrate 10 surface after the substrate and growth promoter regions 12 (as has been shown above in FIG. 2A) have been exposed to a plasma. Preferably the substrate 10 is a silicon wafer, but it can be any material consistent with the art of semiconductor manufacturing. The substrate 10 can consist of one single material, or it can consist of any number of different material layers. The nanoparticles 14 vary in size between about 1 nm and 50 nm and are distributed in a random and fairly uniform arrangement on the surface of the substrate 10. Alternatively, there can be regions of the substrate 10 where there are very many nanoparticles 14, and there can be regions where there are few or no nanoparticles 14 (not shown). In addition to the nanoparticles 14, there can be larger regions of growth promoter (not shown) left as residues of the original growth promoter regions 12 as were shown above in FIG. 2B. FIG. 5B shows a network 18 of nanostructures 16 as formed from the growth promoter nanoparticles 14. Remaining growth promoter nanoparticles 14 are not shown in FIG. 5B. Preferably, the nanostructure network 18 is formed using a chemical vapor deposition process. Preferably, the nanostructure network 18 is very flat, or planar, and very close to, or substantially in contact with, the substrate 10.

Steps according to one processing arrangement are illustrated in FIGS. 5C and 5D, which follow on from FIG. 5B. In FIG. 5C, an array of electrodes 26 has been contacted to the nanostructure network 18, as was discussed for Step 440 in FIG. 4 above. The electrodes 26 contact the substrate 10 through openings in the nanostructure network 18. In FIG. 5D, some regions of the nanostructure network 18 have been removed from a portion of the substrate 10. The removal can be done using a resist-lithography-etch process, the steps of which are not shown in FIG. 5, but are is well known in the semiconductor arts. The substrate 10 is coated with resist and then exposed to either light or e-beam in a lithography process. Resist remains covering the electrodes and regions where it is desired to retain the nanostructure network 18. One or more etch processes can be performed on the substrate 10 to remove the exposed areas that contain both regions of nanostructure network 18 and growth promoter nanoparticles 14, and then the remaining resist is removed in FIG. 5D, regions 24 of the nanostructure network 18 remain on the substrate, many of which have contact with two electrodes 26, thus forming an array 28 of nanostructure devices. The regions 24 are discontinuous across the surface of the substrate 10. In FIG. 5D, the regions 24 are shown in a rectangular pattern, although any size, pattern, or random arrangement of regions 24 is possible by selection of an appropriate resist exposure pattern. Although FIG. 5D shows most nanostructure network regions 24 contacted to two electrodes 26, it should be understood that there are other arrangements that fall within the scope of this embodiment. For some applications, it may be desirable to provide more than two electrodes 26 to some nanostructure network regions 24. For different applications, it may be desirable to leave more nanostructure network regions 24 without electrodes or to contact electrodes 26 to additional nanostructure network regions 24.

Steps according to an alternative processing arrangement are illustrated in FIGS. 5C′ and 5D′, which follow on from FIG. 5B. In FIG. 5C′, regions of the nanostructure network 18 have been removed from a portion of the substrate 10. The removal can be done using a resist-lithography-etch process, the steps of which are not shown in FIG. 5, but are well known in the semiconductor arts. The substrate 10 is coated with resist and then exposed to either light or e-beam in a lithography process. Resist remains covering regions where it is desired to retain the nanostructure network 18. One or more etch processes can be performed on the substrate 10 to remove the exposed areas that contain both regions of nanostructure network 18 and growth promoter nanoparticles 14, and then the remaining resist is removed. Regions 24 of the nanostructure network 18 remain on the substrate. The regions 24 are discontinuous across the surface of the substrate 10. In FIG. 5C′, the regions 24 are shown in a rectangular pattern, although any size, pattern, or random arrangement of regions 24 is possible by selection of an appropriate resist exposure pattern. In FIG. 5D′, an array of electrodes 26 has been contacted to the nanostructure network regions 24, as was discussed for Step 440 in FIG. 4 above, thus forming an array 28 of nanostructure devices on the substrate 10. In some arrangements, the electrodes 26 are positioned so that each electrode 26 is contacted partially to the bare substrate 10 surface and partially to the nanostructure network region 24. In other arrangements, the electrodes 26 are positioned mostly or completely on the nanostructure network regions 24 and make contact with the substrate 10 through openings in the nanostructure network. Combinations of these arrangements are also possible. Although FIG. 5D′ shows most nanostructure network regions 24 contacted to two electrodes 26, it should be understood that there are other arrangements that fall within the scope of this embodiment. For some applications, it may be desirable to provide more than two electrodes 26 to some nanostructure network regions 24. For different applications, it may be desirable to leave even more nanostructure network regions 24 without electrodes or to contact electrodes 26 to every nanostructure network region 24.

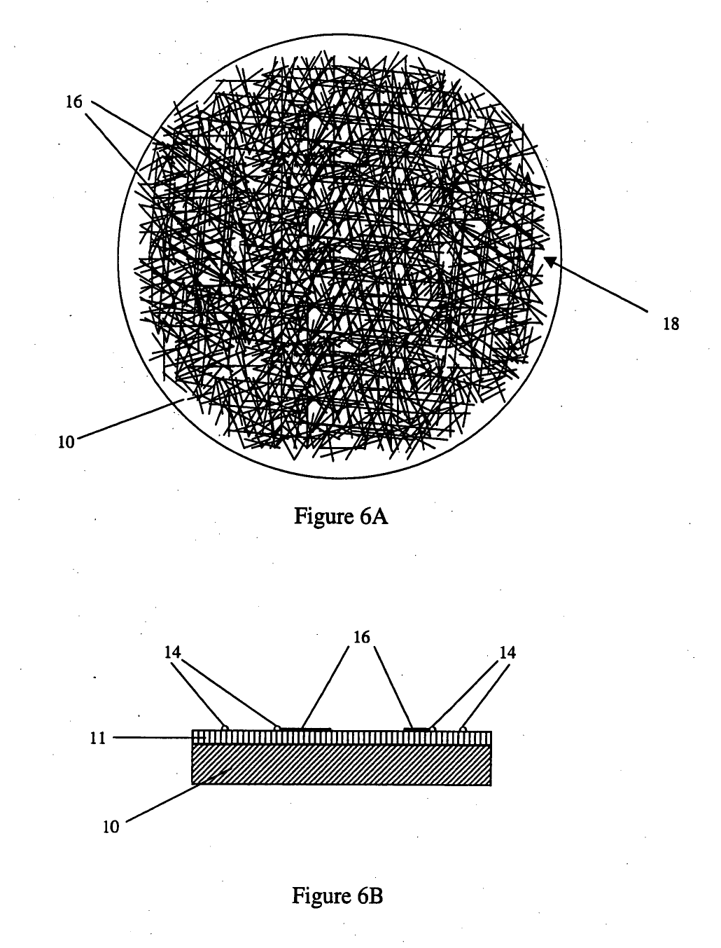

FIG. 6A shows a top view of a nanostructure dispersion 18, disposed on a substrate 10 according to an illustrated embodiment of the invention. Although they are not shown, there are also growth promoter particles on the substrate 10. FIG. 6B shows a cross-section view of two representative individual nanostructures 16 from the nanostructure dispersion 18 of FIG. 6A. The nanostructures 16 are in contact with a top layer 11 of the substrate 10 and extend over the surface of the top layer 11. Preferably the underlying substrate 10 is a silicon wafer, but both the top layer 11 and the substrate 10 can contain any materials consistent with the art of semiconductor manufacturing, as has been described above with reference to FIG. 1. The substrate 10 can consist of one single material or any number of different material layers. In other arrangements, there is no top layer 11, and the nanostructures 16 are directly in contact with the substrate 10. At one end of each of the nanostructures 16, there is a growth promoter nanoparticle 14. In addition, there may be a number of growth promoter nanoparticles 14 dispersed on the top layer 11. Some of the growth promoter nanoparticles 14 may not be associated with nanostructures 16. The growth promoter nanoparticles 14 have been described in detail above with reference to FIGS. 1 and 2. Preferably, the growth nanoparticles 14 range from about 1 nm to about 50 nm in size. The nanostructures can be made of carbon or of any other materials known to form nanostructures, such as metals and semimetals. Nanostructures, such as single-wall carbon nanotubes and metal nanowires are desirable for many applications. A plurality of electrodes (not shown) can be disposed onto the nanostructure dispersion such that at least some of the electrodes are in electrical communication with one another through at least one nanostructure 16.

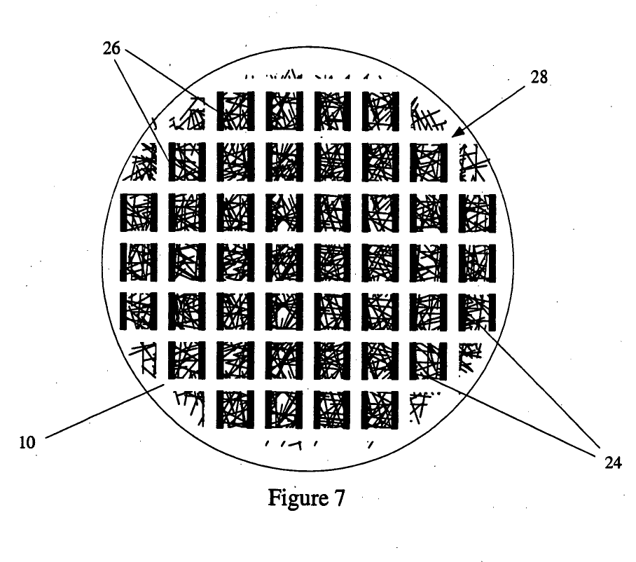

FIG. 7 shows a top view of an array 28 of nanostructure devices according to an illustrated embodiment of the invention. Preferably the substrate 10 is a silicon wafer, but it can be any material consistent with the art of semiconductor manufacturing. The substrate 10 can consist of one single material or of any number of different material layers. There is a dispersion of nanostructures disposed discontinuously on the substrate 10 as nanostructure regions 24. Some of the nanostructure dispersion regions 24 can be in contact with one another (not shown). In addition, there may be a number of growth promoter nanoparticles (not shown) dispersed within the nanostructure dispersion regions 24, some of which growth promoter nanoparticles are associated with the nanostructures, and some of which are not associated with the nanostructures, as was described above for FIG. 6B. The nanostructures can be made of carbon or of any other materials known to form nanostructures, such as metals and semimetals. The nanostructures can contain elements such as carbon, silicon, germanium, arsenic, gallium, aluminum, boron, phosphorus, indium, tin, molybdenum, tungsten, vanadium, sulfur, selenium, and tellurium. Nanotubes, for example, single-wall carbon nanotubes and metal nanowires are desirable for many applications. An array of electrodes 26 is in contact with the dispersion of nanostructures. As shown in FIG. 7, the nanostructure dispersion regions 24 can be in contact with two electrodes 26. Each pair of electrodes 26 is in electrical communication with one another through at least one nanostructure 16 within the associated nanostructure dispersion region 24. Alternatively, more than two electrodes 26 can be contacted to at least some nanostructure dispersion regions 24. In other arrangements, many nanostructure dispersion regions 24 have no electrodes 26 or all nanostructure dispersion regions 24 have electrodes 26. Electrical leads (not shown) can be contacted to the electrodes 26 to provide communication among the nanostructure devices and with outside electrical elements (not shown).

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. An array of nanostructure devices, comprising:
a substrate;
a dispersion of nanostructures disposed discontinuously on the substrate; and
an array of electrodes in contact with the dispersion of nanostructures and with the substrate surface.

2. The array of claim 1, wherein the substrate comprises a material selected from the group consisting of silicon, silicon oxides, silicon nitride, alumina, and quartz.

3. The array of claim 1, wherein the nanostructures are selected from the group consisting of nanotubes and nanowires.

4. The array of claim 1, wherein the dispersion of nanostructures is approximately planar and substantially in contact with the substrate.

5. The array of claim 1, wherein the dispersion of nanostructures comprises at least one element selected from the group consisting of C, Si, Ge, As, Ga, Al, B, P, In, Sn, Mo, W, V, S, Se, and Te.

6. The array of claim 1, wherein the dispersion of nanostructures comprises regions containing nanostructures interspersed with areas containing no nanostructures

7. The array of claim 6, wherein at least one region containing the nanostructures provides electrical communication between at least two electrodes.

8. An array of nanostructure transistors, comprising:
a substrate;
a dispersion of nanostructures disposed discontinuously on the substrate;
an array of electrodes in contact with the dispersion of nanostructures and with the substrate surface; and
a first gate electrode capable of biasing at least a portion of the dispersion of nanostructures.

9. The array of claim 8, wherein the dispersion of nanostructures comprises regions containing nanostructures interspersed with areas containing no nanostructures

10. The array of claim 9, wherein at least one region containing the nanostructures provides electrical communication between at least two electrodes.

11. A nanostructure device, comprising:
(a) a substrate having a surface;
(b) a dispersion including a plurality of individual nanostructures disposed adjacent the surface of the substrate,
(i) wherein the individual nanostructures are each conductive or semiconductive;
(ii) wherein the plurality of nanostructures are positioned having a plurality of electrical connections between adjacent nanostructures so as to form at least one network region; and
(c) at least one spaced-apart electrode pair including a first electrode and a second electrode, each electrode in electrical communication with at least a portion of the network region;
(d) wherein the nanostructures of the network region complete an electrical communication between the first electrode and the second electrode by means of the electrical connections between adjacent nanostructures of the network region.

12. The device of claim 11, wherein at least one of the first electrode and the second electrode has an electrode position with respect to the substrate, and the electrical connection between the first electrode and the second electrode is provided without a specific correspondence between electrode position and a nanostructure position.

13. The device of claim 11, wherein the electrical communication between the first electrode and the second electrode is provided having substantially none of the individual nanostructures of the network region in physical contact with both of the first electrode and the second electrode.

14. The device of claim 11, wherein the disposition of the individual nanostructures of the network region are substantially random with respect to the position of adjacent nanostructures.

15. The device of claim 11, wherein the plurality of individual nanostructures includes one or more nanostructures selected from the group consisting essentially of carbon nanotubes, bundles of carbon nanotubes, and nanowires.

16. The device of claim 11, wherein the plurality of individual nanostructures includes one or more single walled carbon nanotubes.

17. The device of claim 11, wherein the substrate comprises a material selected from the group consisting of silicon, silicon oxides, silicon nitride, alumina, and quartz.

18. The device of claim 11, wherein the dispersion of nanostructures is approximately planar and substantially in contact with the substrate.

19. The device of claim 11, wherein the dispersion of nanostructures comprises at least one element selected from the group consisting of C, Si, Ge, As, Ga, Al, B, P, In, Sn, Mo, W, V, S, Se, and Te.

20. The device of claim 11, further comprising at least one gate electrode capable of biasing at least a portion of the dispersion of nanostructures.

21. An array of nanostructure devices, comprising:
(a) a substrate having a surface;
(b) a dispersion including a plurality of individual nanostructures disposed adjacent the surface of the substrate,
(i) wherein the individual nanostructures are each conductive or semiconductive;
(ii) wherein the plurality of nanostructures positioned to form a plurality of network regions, each network region including a plurality of nanostructures having of electrical connections between adjacent nanostructures of the network region; and
(c) a plurality of electrodes, having at least one of the plurality of electrodes in electrical communication with at least a portion of each network region.

22. The array of claim 21, wherein the plurality of network regions are discontinuous.

23. The array of claim 22, wherein the plurality of discontinuous network regions includes areas containing nanostructures interspersed with areas containing substantially no nanostructures.

24. The array of claim 22, wherein at least one network region is in electrical communication with at least two of the plurality of electrodes,

25. The array of claim 21, wherein the disposition of the individual nanostructures of the network region are substantially random with respect to the position of adjacent nanostructures.

26. The array of claim 21, wherein the plurality of individual nanostructures includes one or more nanostructures selected from the group consisting essentially of carbon nanotubes, bundles of carbon nanotubes, and nanowires.

27. The array of claim 21, wherein the plurality of individual nanostructures includes one or more single walled carbon nanotubes.

28. The array of claim 21, wherein the substrate comprises a material selected from the group consisting of silicon, silicon oxides, silicon nitride, alumina, and quartz.

29. The array of claim 21, wherein the dispersion of nanostructures is approximately planar and substantially in contact with the substrate.

30. The array of claim 21, wherein the dispersion of nanostructures comprises at least one element selected from the group consisting of C, Si, Ge, As, Ga, Al, B, P, In, Sn, Mo, W, V, S, Se, and Te.

31. The array of claim 21, further comprising at least one gate electrode capable of biasing at least a portion of the dispersion of nanostructures.

32. The array of claim 21:
(a) wherein the plurality of electrodes comprises at least a first electrode and the second electrode, both first electrode and the second electrode being in electrical communication with at least a portion of a first one of the plurality of network regions; and
(b) wherein the nanostructures of the first network region complete an electrical communication between the first electrode and the second electrode by means of the electrical connections between adjacent nanostructures of the first network region.

33. The array of claim 32, wherein at least one of the first electrode and the second electrode has an electrode position with respect to the substrate, and the electrical connection between the first electrode and the second electrode is provided without a specific correspondence between electrode position and a nanostructure position.

34. The array of claim 32, wherein the electrical communication between the first electrode and the second electrode is provided having substantially none of the individual nanostructures of the first network region in physical contact with both of the first electrode and the second electrode.
